(19) United States
(12) Patent Application Publication
(10) Pub. No.: US 2014/0195730 A1
(43) Pub. Date: Jul. 10, 2014

(54) ROBUST AND SECURE MEMORY SUBSYSTEM

(71) Applicant: Dannie Gerrit Feekes, El Dorado Hills, CA (US)

(72) Inventor: Dannie Gerrit Feekes, El Dorado Hills, CA (US)

(21) Appl. No.: 14/149,780

(22) Filed: Jan. 7, 2014

Related U.S. Application Data
(60) Provisional application No. 61/749,677, filed on Jan. 7, 2013.

(51) Int. Cl. G11C 11/406; G06F 12/14; G06F 12/08

(52) U.S. Cl. CPC G11C 11/40607; G06F 12/0864; G06F 12/14
USPC 711/105; 711/128

(57) ABSTRACT

The present disclosure is generally directed to a more robust memory subsystem having a an improved architecture for managing a memory space. In one embodiment, a method is provided that includes receiving a memory access request from a memory controller and attempting to access the requested data from a first level of memory maintained on the memory device that contains the map cache. The method is further configured to perform a lookup in the map cache to determine whether the requested address is resident in the first level of memory. If the requested data is not resident in the first level of memory, the method causes a re-map address to be calculated that identifies a location of the requested data in a lower level of memory. Conversely, if the requested data is resident in the first level of memory, the method provides the memory controller with access to the requested data.

### CROSS-REFERENCE TO RELATED APPLICATION

This application claims the benefit of Provisional Application No. 61/749,677, filed Jan. 7, 2013, which is hereby incorporated by reference.

### BACKGROUND

The speed at which computer processors operate has been continually increasing. Specifically, decreasing the size of the semiconductor transistors and the operating voltages of these transistors has allowed processor clocks to run at faster rates. However, the performance of DRAM-based main memory systems that provide data to these faster processors have not kept pace with the increasingly faster processors. Thus, DRAM based main memory systems became a bottleneck for computer performance. In this regard, Random Access Memories (RAMs) are well known in the art. A typical RAM has a memory array wherein every location is addressable and freely accessible by providing the correct corresponding address. Dynamic RAMs (DRAMs) are dense RAMs with a very small memory cell. High performance Static RAMs (SRAMs) are somewhat less dense (and generally more expensive per bit) than DRAMs, but expend more power in each access to achieve speed, i.e., provide better access times than DRAMs at the cost of higher power. In a personal computer dominated environment the vast majority of research, development, and improvements relating to RAM memories has gone into increasing the memory densities to prevent performance bottlenecks.

In a typical data processing system, the bulk of the main memory is DRAM with faster SRAM in cache memory, closer to the processor or microprocessor. These types of ‘hybrid’ or ‘hierarchical’ memory systems have played an important role in the computer architecture landscape. The time it takes for a processor to retrieve a needed piece of data or an instruction from main memory is quite large relative to the cycle time of the processor. By putting one or more levels of cache in between the processor and main memory, the architecture of the memory hierarchy has reduced the average time it takes for a processor's read/write request to be serviced. This technique has been effective in certain respects. Traditionally, if there is no memory hierarchy in place (meaning the processor's request is only fulfilled by the main memory), then the processor must either stall or work on another task until its request has been serviced by main memory.

Certain aspects of hybrid or hierarchal memory subsystems are currently in use for the purpose of displacing one memory technology with lesser qualities (be it power, cost, speed, etc.) for a memory technology with superior qualities. The trade-off is to minimize cost/power while maximizing performance. The typical implementation is one in which a cache controller is used to map and manage an operating system (“OS”) visible memory space between a plurality of memory devices of different technologies (e.g. WIO2, DRAM, and PCM). Also, the cache controllers typically consist of a memory located physically in the cache controller that serves the purpose of partial and/or full mapping of the OS visible memory space. This design of existing hierarchical memory subsystems can be improved upon with a memory subsystem architecture of reduced cost, lower latency, faster read access time, and low power. Moreover, existing memory subsystems are PC-centric in nature and not designed to support enhanced security features and data protection schemas that are increasingly important for networked and more mobile devices.

### SUMMARY

This Summary is provided to introduce a selection of concepts in a simplified form that are further described below in the Description. This Summary is not intended to identify key features or essential features of the claimed subject matter, nor is the Summary to be used as an aid in determining the scope of the claimed subject matter.

The present disclosure is generally directed to a more robust memory subsystem having a an improved architecture for managing a memory space. In one embodiment, a method is provided that includes receiving a memory access request from a memory controller and attempting to access the requested data from a first level of memory maintained on the memory device that contains a map cache. The method is further configured to perform a lookup in the map cache to determine whether the requested address is resident in the first level of memory. If the requested data is not resident in the first level of memory, the method causes a re-map address to be calculated that identifies a location of the requested data in a lower level of memory. Conversely, if the requested data is resident in the first level of memory, the method provides the memory controller with access to the requested data.

### DESCRIPTION OF THE DRAWINGS

The foregoing aspects and many of the attendant advantages will become more readily appreciated as the same become better understood by reference to the following detailed description, when taken in conjunction with the accompanying drawings, wherein:

FIG. 1 is a block diagram illustrating modules of a memory device configured to manage a memory space in accordance with embodiments of the present disclosure;

FIG. 2 is a flow diagram illustrating a method for accessing data in a memory space in accordance with embodiments of the present disclosure;

FIG. 3 is a block diagram illustrating a memory device configured to managed a memory space in accordance with embodiments of the present disclosure;

FIG. 4 is an illustration depicting a schema for mapping data in memory in accordance with embodiments of the present disclosure;

FIG. 5 is a flow diagram illustrating a method for accessing data in a memory space in accordance with embodiments of the present disclosure;

FIG. 6 is an illustration depicting a schema for mapping data in memory in accordance with embodiments of the present disclosure;

FIG. 7 is a flow diagram illustrating a method for accessing data in a memory space in accordance with embodiments of the present disclosure; and

FIG. 8 is a block diagram illustrating a memory device configured to managed a memory space in accordance with embodiments of the present disclosure.

### DESCRIPTION

The description set forth below in connection with the appended drawings where like numerals reference like elements is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the disclosure to the precise forms disclosed. Similarly, any steps described herein may be interchangeable with other steps, or combinations of steps, in order to achieve the same or substantially similar result.

In one embodiment, aspects of the present disclosure provide a memory system having a mapping cache integrated into the first level of memory that is managed. The disclosed design of the mapping cache allows the memory subsystem controller to readily remap the OS visible memory space. By providing memory mapping functionality within the first level of memory that is managed, data previously maintained in a cache (such as a L1 and/or L2 cache) can be moved to a more cost effective memory such as RAM memory. In this regard, the memory subsystem controller provided by the present disclosure may readily migrate code and data between multiple levels of memory in various embodiments to maximize the different power, performance, and price tradeoffs of the available memory technologies based on data usage. Moreover, the configuration of the memory systems provided by the present disclosure supports secure enclaves where data is protected by enhanced security measures. In one embodiment, a secure enclave is configured to make it physically impossible for code or devices to access certain areas of memory without a user being biometrically authenticated since the OS visible memory space is mapped in hardware logic and not accessible to software processes. The disclosed embodiments include a mapping architecture which supports inclusive and exclusive caching schemes and is suitable for use with a number of different memory technologies. Additional embodiments and advantages of the memory system and mapping functionality will become more readily apparent from the descriptions that follow.

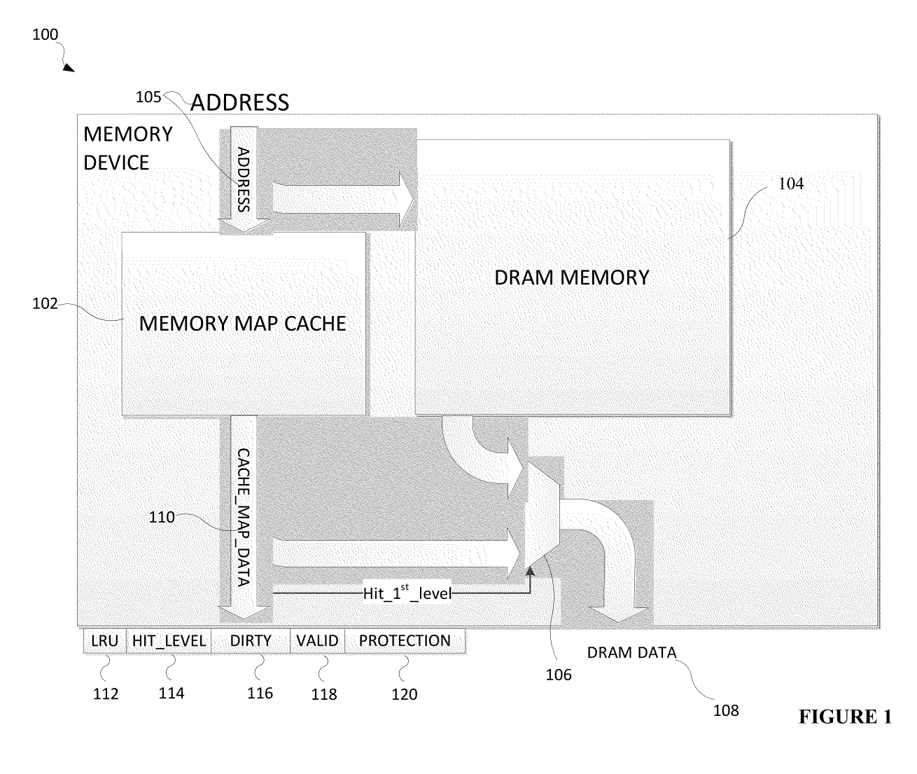

Now with reference to FIG. 1, a memory device 100 such as a DRAM memory device in accordance with one embodiment of the present disclosure will be described. As illustrated in FIG. 1, the memory device 100 includes a memory map cache 102 that is resident in the memory device 100 and a DRAM memory 104 consisting of an array of memory cells. In some cases, embodiments of the present disclosure may be used with multiple types of memory or with a memory that is included on a device with multiple other types of memory. The memory technology depicted in FIG. 1 is DRAM but other memory technology may be utilized without departing from the scope of the claimed subject matter. The memory types may include volatile and non-volatile memory. Volatile memories may include, but are not limited to static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other device capable of storing data through an interruption of power. Embodiments of the present disclosure may generally be used with any type of memory or device capable of storing data. The term “memory” as used herein includes any device capable of storing data which could include devices such as storage controllers, flash controllers, buffers, data structures, and the like. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In other instances, the memory may be provided as a memory device which is used with a separate memory controller device or processor device.

In the embodiment illustrated in FIG. 1, the memory map cache 102 is allocated a subset of DRAM memory cells within the memory device 100 for storing address cache data. In other words, the memory map cache 102 consists of a small amount of DRAM that maintains the addresses of the data that is resident in an OS visible memory space. In some systems, a cache close to a processor (such as a L1 and/or L2 cache) that is typically composed of high density RAM memory (e.g. “SRAM”) maintains an address cache which defines certain attributes of the pages in memory. Unfortunately, the address cache in these systems has grown large and may not be completely maintained in cache memory in all instances and is also expensive and consumers a large amount of power. A fully associative cache may not be provided when only a partial address cache can be maintained in near memory which has a number of drawbacks. In one aspect, the present disclosure is able to move the map cache into a first level of managed memory which, in the example depicted in FIG. 1, is the DRAM memory 104. This design allows a fully associative memory map cache 102 to be provided without address cache data having to be maintained, either wholly or partially, in near memory. As illustrated in FIG. 1, the memory device 100 provided by the present disclosure is further configured to resolve a memory address for data in the first level of memory (i.e. the DRAM memory 104) in parallel to attempting a read operation. When a memory request identifying the address 105 is received, the request can be provided in parallel to the memory map cache 102 and the DRAM memory 104. In an alternative embodiment, the present disclosure implements a power saving mode in which the requested data is accessed subsequent to a determination being made that there is a first level “hit”. In this instance, a request is not provided in parallel to the DRAM memory 104 in order to minimize power consumption. In any event, the memory map cache 102 performs a lookup to determine whether the memory request is currently present in the DRAM memory 104. In instances when there is a first level “hit” (which, in this example is a memory request that is present in the DRAM memory 104), the Cache Map Data 110 returned to a memory controller (not illustrated) may indicate that the requested data will be available on the DRAM DQ lines to read in accordance with existing systems. Conversely, in instances when there is a first level “miss”, (which, in this example is a memory request that is not present in the DRAM memory 104), the Cache Map Data 110 returned to a memory controller will indicate that the data at the requested address 105 is not present in the first level of memory. Moreover, in the case of a first level “miss,” a re-map address may be optionally provided as input into the Multiplexer 106 and multiplexed onto the DRAM data 108 stream that is output by the memory device 100. Accordingly, on the same operation, either the read succeeds or a re-map address is provided that may be used by a memory controller to identify the location where the requested data may be accessed in a lower level of memory.

By providing memory mapping functionality within the first level of managed memory (i.e. the DRAM memory device 100), a tag cache typically maintained in near memory can be integrated into in less expensive RAM memory. In the embodiment illustrated in FIG. 1, the memory map cache 102 implements memory mapping functionality to map and manage an OS visible memory space between a plurality of hierarchical memory devices that potentially utilize different technologies (e.g. WIO2, DRAM, PCM, etc.). The data maintained by the memory map cache 102 and provided to a memory controller enables certain enhanced security features. As described in further detail below, the memory subsystems and architecture provided by the present disclosure enables a memory controller to partition the OS visible memory space into secure enclaves which make it physically impossible for code or devices to access regions of memory without an enhanced authentication. Moreover, the functionality of the memory device 100 allows a memory controller to migrate code and data between multiple levels of memory devices (not shown) to maximize different power, performance, and price tradeoffs.

In one aspect, the memory device 100 provided by the present disclosure implements a mapping scheme in which a common row and column addresses are used in the map cache 102 and the first level of memory (e.g. the DRAM Memory 104). As illustrated in FIG. 1, the memory map cache is integrated into a memory device that also provides the first level of memory. This disclosed architecture provides an opportunity for performance improvements in satisfying memory requests. Specifically, the map cache page index and offset may use the same number of address bits as the column and row address of the first level of memory. As a result, the map cache 102 and the DRAM Memory 104 may both be present for a given memory address on the same clock cycle which provides a solution that has minimum read latency.

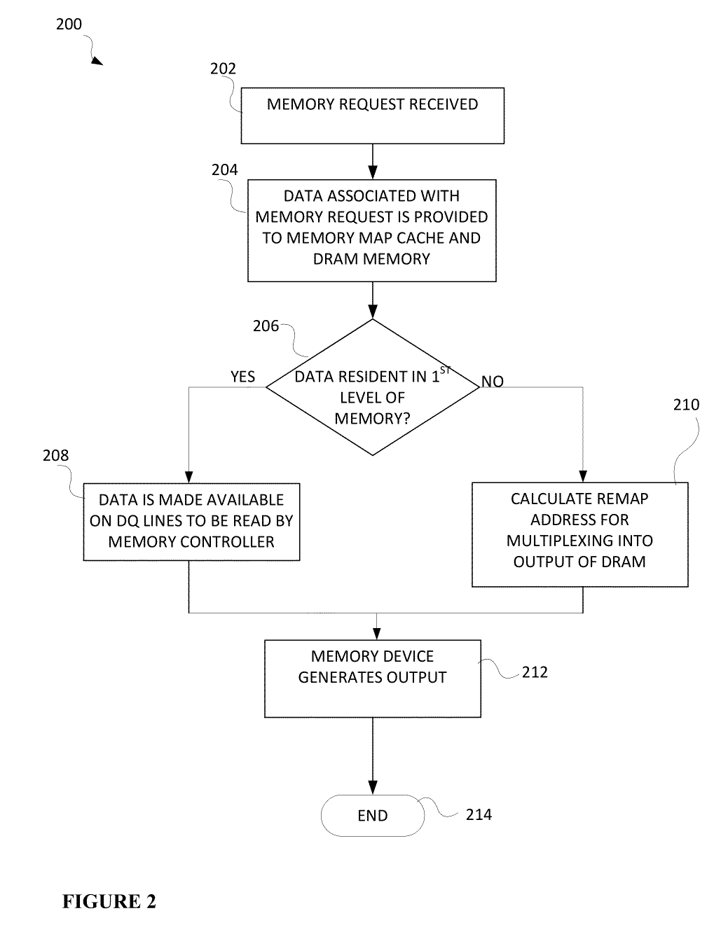

Now with reference to FIG. 2, a method 200 for handling a memory request in accordance with the present disclosure will be described. In general, the method 200 illustrates the processing performed by the memory device 100 depicted in FIG. 1 in handing a read operation. However, one skilled in the art and others and others will recognize that the memory device 100 depicted and described herein, provides an architecture that is applicable in other contexts than just satisfying a read operation.

As illustrated in FIG. 2, the method 200 begins at block 202 where a memory request to read certain data in memory is received. For example, the memory device 100 depicted in FIG. 1 may receive a memory request from an internal or external memory controller which identifies a particular memory address being requested at block 202.

At block 204 of the method 200, data associated with the memory request is provided to both the memory map cache 102 and the DRAM memory 104 (FIG. 1). Aspects of the present disclosure may be configured to perform certain actions in parallel to improve the performance of a memory device. In particular, the work of providing cache data performed by the memory map cache 102 may be completed in parallel with reading/writing data from/to the DRAM memory 104. To support the parallel nature of the memory device 100 provided by the present disclosure, requests from a memory controller are transmitted to both the memory map cache 102 and the DRAM memory 104, at block 204.

At decision block 206 of the method 200, a determination is made regarding whether the requested data is resident in the first level of managed memory. Stated differently, a determination is made at block 206 regarding whether the memory request received at block 202 is a “hit” to the data maintained in the memory device 100 (FIG. 1). At block 206, a lookup is performed in the memory map cache 102 to determine whether the requested address is resident in the first level of managed memory (i.e. the DRAM memory 104). As described above with reference to FIG. 1, the memory map cache 102 is configured to map OS visible data between a plurality of memory/storage devices. If the results of the lookup in the memory map cache 102 indicate that the requested data is not resident in the first level of managed memory, then a determination is made that the request resulted in a cache “miss” and the method 200 proceeds to block 210, described in further detail below. Conversely, if the requested data is resident in the first level of managed memory, then a cache “hit” occurred and the method 200 proceeds to block 208.

At block 208 of the method 200, the requested data is made available on so called DQ lines for the memory controller to read in accordance with existing systems. DQ lines are physical connections between a memory controller and memory. A data valid window is defined which provides a specific period of time when the DQ lines are active so that the memory controller is able to access the requested data. The exact manner in which data is provided to the memory controller may depend on the specific memory devices utilized. However, it should be well understood that the method 200 described herein is applicable regardless of which specific memory architecture is employed.

At block 210 of the method 200, a re-map address for the data requested at block 202 is calculated by the memory map cache 102. If block 210 is reached, than a determination was made at block 206 that the data being requested is not resident in the first level of managed memory. When the requested data is outside the first level of memory, an external memory address for the requested data may be calculated using techniques described in further detail below. As mentioned above with reference to FIG. 1, the re-map address may be provided to a memory controller. Accordingly, in instances when a memory “miss” occurs, another memory request does not have to be issued to the memory device 100 in order to access the requested data. Instead, the memory controller may use the calculated re-map address to obtain the requested data directly from a different memory device.

As further illustrated in FIG. 2, at block 212, data that is responsive to the memory request received at block 202 is output by the memory device 100 provided by the present disclosure. The data that is output may include the Cache Map Data 110 and the DRAM data 108 mentioned above with reference to FIG. 1 and described in further detail below. Then, the method 200 proceeds to block 214, where it terminates.

Now with reference again to FIG. 1, the output generated by the memory device 100 will be discussed in additional detail. As illustrated in FIG. 1 and in accordance with one embodiment, the memory device 100 generates two types of output, namely: the DRAM data 108 output and the Cache Map Data 110. The DRAM data 108 output may include the data requested by a memory controller and/or hit/miss information. In the depicted embodiment, the Cache Map Data 110 comprises a data set that includes LRU field 112, HIT LEVEL field 114, DIRTY field 116, VALID field 118, and PROTECTION field 120. This data may be provided to the memory controller and used to implement certain functionality described in further detail below. One skilled in the art will recognize that the LRU field (Least Recently Used) 112 is typically comprised of age bits that are used for tracking the time period in which certain memory locations are accessed. The HIT LEVEL field 114 in the Cache Map Data 110 identifies the level in memory where a requested memory address is located. The VALID field 118 may contain bits that are used to indicate that a block contains data that is still valid and associated with the specified memory address. The DIRTY field 116 contains bits that indicate whether an address has been written to and subsequently modified. Finally, the Cache Map Data 110 output, in this example, includes a PROTECTION field 120 having data which indicates whether enhanced security measures are being used to restrict or limit access to data associated with specific memory addresses. The present disclosure is configured to physically restrict access to blocks of memory without enhanced authentication measures being implemented such as the biometric authentication of an authorized user. This aspect of the present disclosure will be described in further detail below. It should be understood that the exact fields maintained in the memory map cache 102 and provided in the Cache Map Data 110 may be different depending on the exact architecture of the memory subsystem and memory technologies being utilized. For example, the fields described with reference to FIG. 1 may vary depending on whether the memory subsystem utilizes an exclusive or inclusive caching architecture among other architectural variables.

It should be well understood that the depictions and descriptions provided with reference to FIGS. 1-2 should be construed as exemplary. In actual embodiments, the memory architecture of a memory subsystem provided by the present disclosure may include additional or fewer components than those depicted in FIG. 1 and/or may be configured in alternative arrangements than described. For example, FIG. 1 depicts a memory subsystem in which the first level of managed memory is DRAM. However, this should be construed as exemplary as the first level of managed memory may be a different type of memory than DRAM without departing from the scope of the claimed subject matter. Aspects of the present disclosure may be configured to work in conjunction with any type of existing or yet to be developed memory technology. Also, FIG. 1 does not depict any lower levels of memory from the first level of managed memory. However, the present disclosure supports a hierarchical memory architecture that includes multiple levels of memory potentially comprised of different memory technologies. In addition, the functionality depicted and described with reference to FIG. 2 is made in the context of a process flow diagram where steps are performed in a particular order. However, at least some of the functionality implemented by the memory device 100 can be performed in parallel without certain steps having to be performed in a particular order. Accordingly, the ordering and number of steps provided above with reference to FIG. 2 should also be construed as exemplary and not limiting.

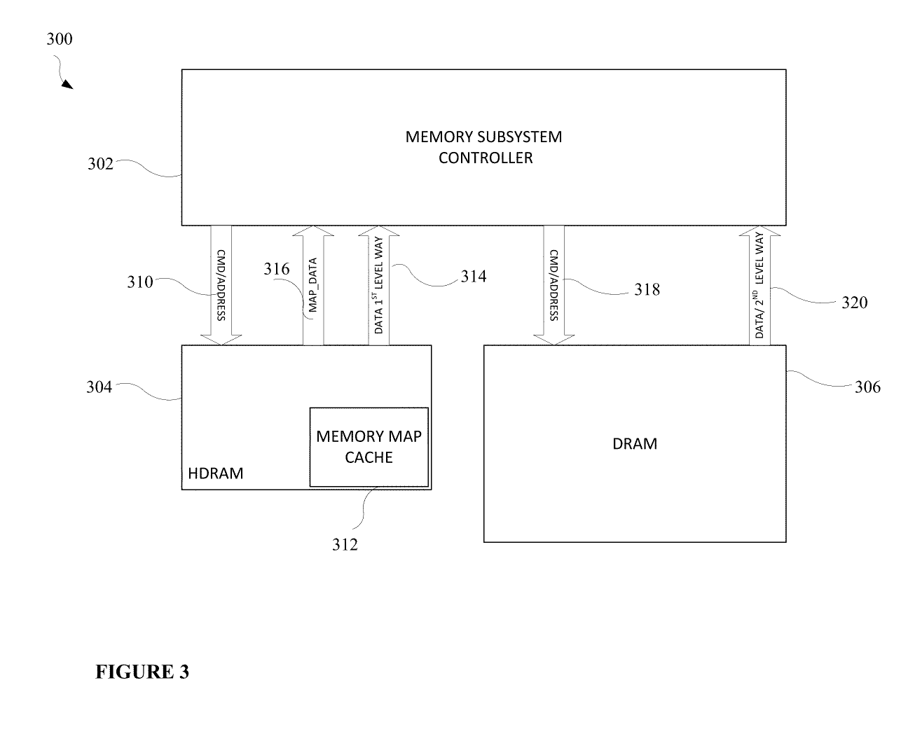

Now with reference to FIG. 3, a hierarchical memory device 300 configured to support both exclusive or inclusive caching architectures in accordance with the present disclosure will be described. In this regard, the memory device 300 illustrated in FIG. 3 includes a Memory Subsystem Controller 302 (“MSS Controller 302”) which manages the flow of data going to and from the Hierarchical Dynamic Random Access Memory 304 (“HDRAM 304”), the DRAM memory 306, and any memory requesting devices (not shown). In this regard, the MSS Controller 302 serves as the interface between system memory and any and all memory requesting devices which will typically include at least one processor (not illustrated). The MSS Controller 302 interprets requests from memory requesting devices in order to locate data addresses in memory and issue commands to access the requested data.

In the exemplary embodiment depicted in FIG. 3, the MSS Controller 302 may issue a command to the HDRAM 304 in the form of the CMD/ADDRESS input 310 to read or write data to or from a particular memory address. When the request is received by the HDRAM 304 provided by the present disclosure, a lookup is performed in the memory map cache 312 to determine whether the requested data is currently present in the HDRAM 304. In turn and as described above with reference to FIGS. 1-2, the DATA 1^{ST} LEVEL WAY output 314 and the MAP_DATA output 316 may be generated by the HDRAM 304 and made available to the MSS Controller 302. In one embodiment, the HDRAM 304 provided by the present disclosure and, specifically, the memory map cache 312 is configured to calculate a re-map address that is provided to the MSS Controller 302 in the case of a first level “miss.” The re-map address is used to identify the location in a lower level of memory (e.g. the DRAM 306) where the requested data is located. In this instance, the MSS Controller 302 may issue a command to the DRAM 306 in the form of the CMD/ADDRESS input 318 to read data from a particular memory address. In response and similar to the description above with reference to FIGS. 1-2, the DATA 2nd LEVEL WAY output 320 is generated and made available to the MSS Controller 302 such that the requested data may then be accessed.

The embodiment depicted in FIG. 3 illustrates a hierarchical memory architecture that supports multiple levels of different types of memory where the memory map cache 312 is integrated into the first level of memory (e.g. the HDRAM 304). Among other advantages to the disclosed design are reduced cost, lower latency, faster read access times, and lower power for memory mapping between a plurality of memory technologies. In this regard, FIG. 3 depicts a first level of managed memory that is HDRAM. However, a principle purpose of the disclosed architecture is to support multiple levels of different types of memory as described above with reference to FIGS. 1-2. Accordingly, while the first and second levels of managed memory depicted in FIG. 3 are HDRAM and DRAM, respectively, other memory technologies and/or devices can be used without departing from the claimed subject matter. By way of example, the different levels of managed memory could be implemented in any device capable of storing data such as a such as a flash, SATA, or IDE storage controller, buffers, among many others.

The memory map cache provided by the present disclosure and depicted in FIGS. 1 and 3 institutes a mapping schema which supports both inclusive and exclusive caching architectures. In this regard, the map cache provided by the present disclosure is configured to map pages in multiple levels of memory. For example, if the system depicted in FIG. 3 applied an exclusive caching architecture, the map cache may be configured to map pages into either the first or second levels of memory and the existence of pages in at least one of the two levels of memory may be guaranteed. If the system depicted in FIG. 3 applied an inclusive caching architecture, the map cache may be configured such that a given page can reside in either the first or second level of memory and all pages will be present in at least the second level of memory. Accordingly, the pages mapped in the first level of memory will typically be a subset of those present in the second level of memory. One skilled in the art that the disclosed concepts can also be readily applied in systems that have more than two levels of memory.

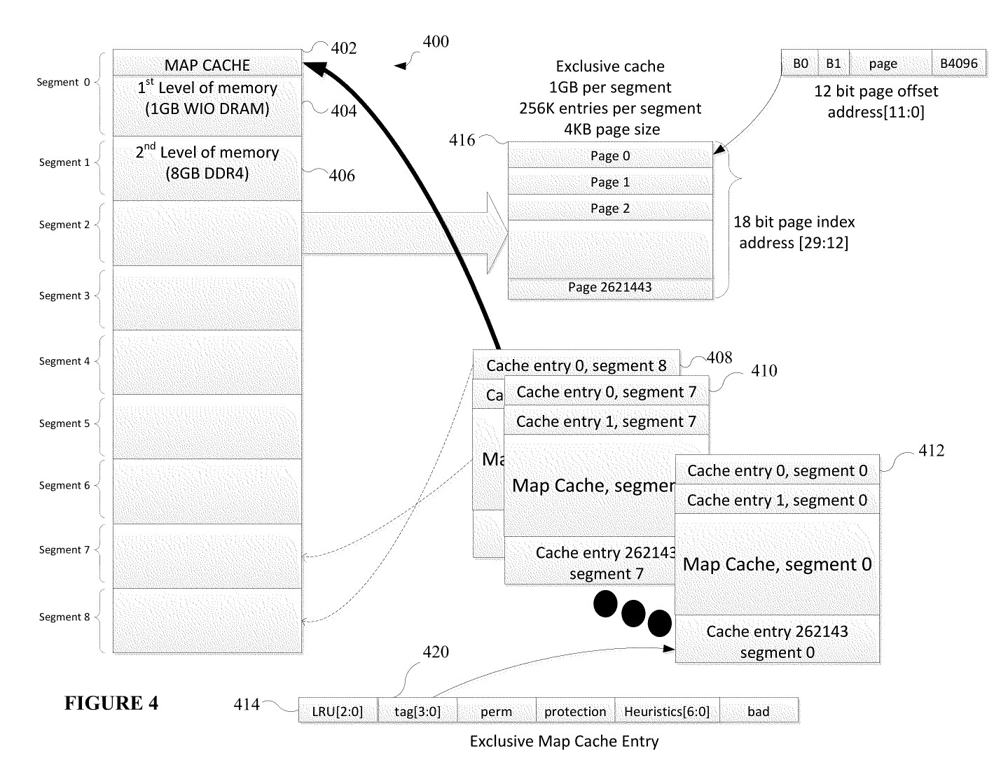

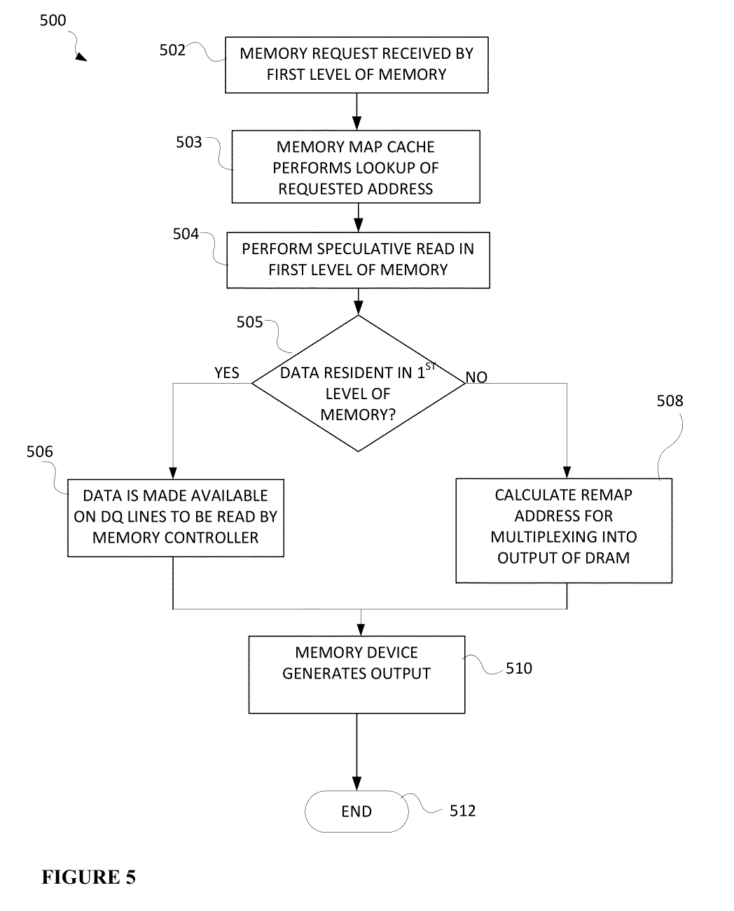

Now with reference to FIGS. 4-5, a memory system that provides an exclusive caching architecture in accordance with the present disclosure is described. Any number of memory mapping schemes may be utilized by aspects of the present disclosure. In the example depicted in FIG. 4, a nine (9) gigabyte memory system 400 is shown with an exclusive map cache 402 provided by the present disclosure. Similar to the descriptions provided above with reference to FIGS. 1-3, the exclusive map cache 402 is resident in the first level of memory 404, which, in this example, is one (1) gigabyte of WIO DRAM memory. As described in further detail below, the first level of memory 404 is configured to provide enhanced security features that limit access to data designated as protected without an appropriate authentication. As further depicted in FIG. 4, the memory system 400 includes a second level of memory 406, which, in this example, is eight (8) gigabyte of DDR4 memory. The memory system 400 depicted in FIG. 4 is divided into 9-memory segments (Segments 0-8) or logical divisions wherein the first level of memory 404 includes memory Segment 0 and the second level of memory 406 is comprised of memory Segments 1-8. Accordingly, the memory system 400 depicted in FIG. 4 includes nine (9) gigabytes of OS visible memory space divided into nine (9) memory segments with one (1) gigabyte for each segment. However, one skilled in the art will recognize that this is merely exemplary as any number of different configurations are possible.

FIG. 4 further depicts cache pages 408-412 from the exclusive map cache 402 that is maintained in the first level of memory 404 by aspects of the present disclosure. In this example, each of the cache pages contains 256K entries which may be ordered as shown. Each cache entry maintained in the exclusive map cache 402 corresponds to and references pages maintained in the memory system 400. Exemplary contents of an exclusive map cache entry 414 is further depicted in FIG. 4 and includes a LRU field, a TAG field, a PERM field, a PROTECT field, and a BAD field. The purpose of the relevant fields in the exemplary map cache entry depicted in FIG. 4 and associated functionality was mentioned above and certain additional aspects may be described in further detail below.

In the example depicted in FIG. 4, each of the memory Segments 0-8 consists of a set of pages 416 with each page being a fixed-length of contiguous memory. As one skilled in the art will recognize, a page is typically the smallest unit of data transferred from the system memory 400 and servers as a unit of data within a memory subsystem. In the exemplary configuration depicted in FIG. 4, an addressing schema that consists of an 18-bit page index and a 12-bit page offset is utilized. However, one skilled in the art will recognize that this is merely exemplary and will typically change depending on the exact size and configuration of memory utilized.

In the exclusive cache mode, a page resides in either the first or second levels of memory 404-406 but will not reside in both levels of memory. As such, a page cannot be invalid as all pages are considered valid regardless of which level of memory the page is located. As mentioned previously, the present disclosure implements enhanced security measures in which access to data that has been designated as protected is restricted without an appropriate authentication. In one embodiment, the map cache provided by the present disclosure is configured to map data that has been designated as protected into a first, second, or lower level of memory. In another embodiment, data designated as protected is exclusively maintained in the first level of memory and cannot be evicted to a lower level of memory. One skilled in the art and others will recognize that certain memory technologies utilize Through Silicon Vias (“TSVs”) which are vertical electrical connections that pass through a wafer or die. For example, the WIO DRAM 404 depicted in FIG. 4 and certain High Bandwidth Memories (“HBM”) may utilize TSVs. These and other memory technologies do not provide a physically accessible interface in which malware or other unauthorized application/entity is able to access data. Data that is not communicated to an external memory be cannot accessed or observed by external entities. In this and other instances, maintaining protected data only in the first level of memory without allowing the data to be evicted provides yet additional security. This embodiment could allow for protected data to be stored without being encrypted as external applications/entities could not physically access data in the first level of memory which would reduce the SoC gate count thereby reducing power consumption and cost.

With reference now to FIG. 5, an exemplary method 500 that illustrates the use of an exclusive map cache in accordance with the present disclosure will be described. The memory map cache and the memory mapping schema provided by the present disclosure supports a more secure way of managing access to memory designated as protected. In this regard, a method 500 will be described with reference to FIG. 5 which illustrates both the logic as well as the interactions between memory components involved in implementing the method 500.

As illustrated in FIG. 5, the method 500 begins at block 502 where a memory request to access data at a specified memory address is communicated to the first level of memory (i.e. the HDRAM 304) that contains the map cache. The memory controller may receive requests to access data at a given location (i.e. 2DEADBEEFh) from one of any number of different memory requesting components (i.e. CPU, GPU, etc.). One skilled in the art will recognize that a memory address is typically represented and accessed using a binary value. For simplicity, the present example utilizes a human-readable address (2DEADBEEFh) which is comprised of a segment identifier (2), a page index (DEEDB) and a page offset (EEF). In turn, the memory controller generates a request to the first level of memory (i.e. the HDRAM 304) such that only a portion of the memory address is supplied to the map cache which, in one embodiment, includes a partial page index of the requested address (1EADB). The map cache provided by the present disclosure is responsible for identifying which memory segment holds the requested address. At block 503, a lookup in the map cache is performed in which the cache entries associated with the partial page index (1EEDB) are read for each of the nine (9) corresponding data segments (i.e. Segments 0-8). In one embodiment, the address bits used in the map cache are typically the same as those used by the DRAM row and column addresses thereby supporting simultaneous reads in the map cache across each of the Segments 0-8. When performing the lookup of the partial page index, the value of the TAG field 420 (FIG. 4) in a map cache entry is used to identify the segment where the requested address is located. For the partial page index (1EEDB) read from the memory map cache for each of the data Segments 0-8 (FIG. 4), the entry that contains the TAG field 420 value of two (2) will yield a ‘hit’ for this exemplary memory address. Stated differently, if the cache entry 414 corresponding to the memory Segment 0 has a TAG field 420 value of two (2) than the requested address (2DEADBEEFh) resides in the first level of memory at address DEADBEEF. In this instance, when a ‘hit’ occurs in the first level of memory, the data and hit/miss information could be made available to a memory controller concurrently.

At optional block 504, a speculative read operation for the requested memory address in the first level of memory is performed. As mentioned previously, aspects of the present disclosure implement functionality so that certain actions may be performed in parallel. The memory request received at block 502 may or may not be requesting data that is currently maintained in the first level of memory. In accordance with one embodiment, the present disclosure performs a speculative read of the memory address within the first level of memory in parallel with performing a lookup in the memory map cache (see block 503 above). In this regard, the address bits used in the memory map cache will typically be the same as those used in the row and column addresses of the first level memory. As a result, a map cache lookup and data read of the first level of memory can be performed in parallel. However, in another embodiment, the memory device provided by the present disclosure implements a power savings mode in which a speculative read operation is not performed in order to minimize power consumption. It may be the case that the data being requested is not currently maintained in the first level of memory. In this instance, the speculative read operation performed at block 504 may not successfully access the requested data. However, if the data requested at block 502 is resident in the first level of memory, than multiple operations within the first level of memory do not have to be performed. If the map cache indicates a hit in Segment 0 (the first level of memory), the requested data is then concurrently available to a memory controller.

At decision block 505 of the method 500, a determination is made regarding whether the requested data is resident in the first level of memory (e.g. the HDRAM 304 or WIO DRAM 404) that maintains the memory map cache. As described above, the memory map cache provided by the present disclosure is configured to map OS visible data between a plurality of memory devices. If the results of the lookup in the memory map cache indicate that the requested data is not resident in the first level of managed memory, then a determination is made that the request resulted in a cache “miss” and the method 500 proceeds to block 508, described in further detail below. Conversely, if the requested data is resident in the first level of managed memory, then a cache “hit” occurred and the method 500 proceeds to block 506.

At block 506 of the method 500, the requested data is made available on the so called DQ lines for the memory controller to read in accordance with existing systems. As described above, DQ lines are physical connections between a memory controller and memory. However, the exact manner in which data is provided to the memory controller may depend on the specific memory devices utilized. Accordingly, it should be well understood that the method 500 described herein may make the requested data available in other ways than described.

At block 508 of the method 500, a re-map address for the data requested at block 502 is calculated. If block 510 is reached, than a determination was made at block 505 that the data being requested is not resident in the first level of managed memory. In other words, the memory request generated a ‘miss’ in the first level of managed memory. In this instance, a hit signal is not asserted in response to the request. Instead, the appropriate memory map data is used to calculate a re-map address for the requested data. In the example depicted in FIG. 4, the location of the memory request may be calculated, at block 510, using the following formula:

Address_{—}2nd_level=(memory segment−1)*1 GB+request_address [29:0]

In turn, the memory controller may re-issue the request to a lower level memory using the results of this calculation.

As further illustrated in FIG. 5, at block 510, data that is responsive to the memory request received at block 502 is output by the first level of memory provided by the present disclosure. This aspect of the present disclosure was described above with reference to FIGS. 1-2. Then, the method 500 proceeds to block 512, where it terminates.

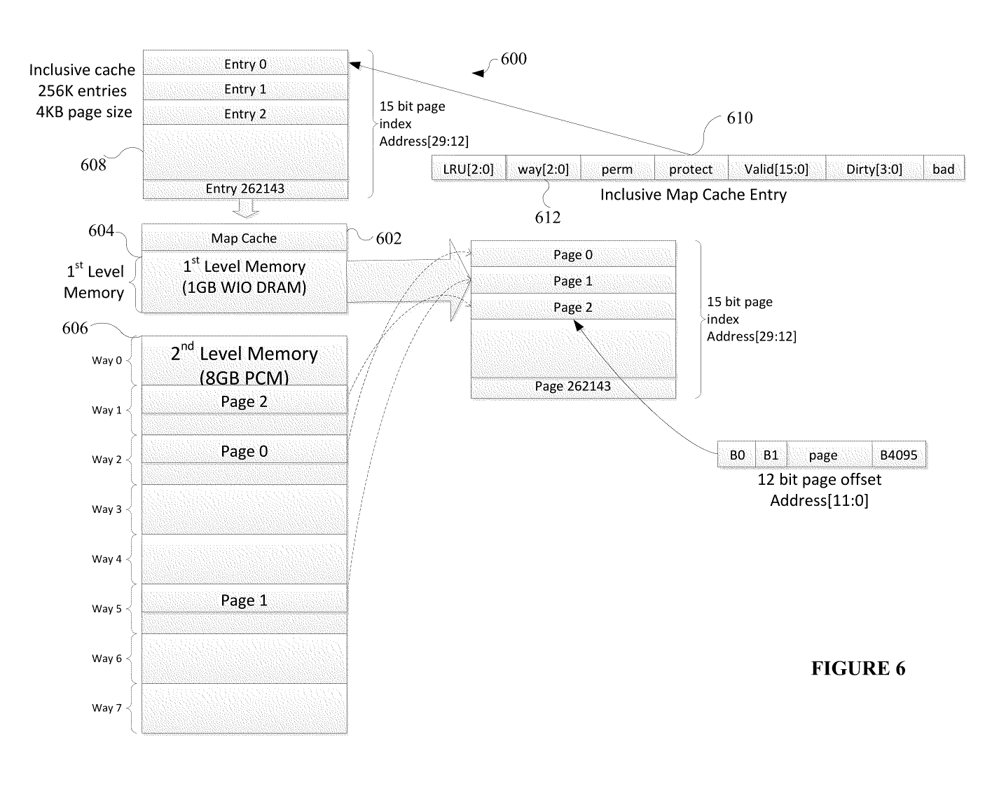

In another exemplary embodiment, an inclusive memory architecture is supported in which a given page can reside in either the first or second level of memory and all pages will be present in the second level of memory. In the example depicted in FIG. 6, a memory system 600 is shown with an inclusive map cache 602 provided by the present disclosure. As illustrated, the inclusive map cache 602 is resident in the first level of memory 604, which, in this example, is 1 gigabyte of WIO DRAM memory. As described in further detail below, the present disclosure is configured to provide enhanced security features that limit access to data designated as protected without an appropriate authentication. As further depicted in FIG. 6, the memory system 600 includes a second level of memory 606, which, in this example, is eight (8) gigabytes of PCM memory. The second level of memory 606 depicted in FIG. 6 is divided into eight (8) ways (e.g. Ways 0-7). Since the memory subsystem utilizes an inclusive caching architecture, eight (8) gigabytes of OS visible memory space are available in this example. The first level of memory 604 contains a subset of the data maintained in the second level of memory 606 which is divided into eight (8) ways with 1 gigabyte for each way. However, one skilled in the art will recognize that this is merely exemplary as any number of different configurations are possible.

FIG. 6 further depicts an set 608 of entries from the inclusive map cache 602 that is maintained in the first level of memory 604 by aspects of the present disclosure. In this example, the set 608 contains 256K entries which may be ordered as shown. Each cache entry maintained in the inclusive map cache 604 corresponds to and references pages maintained in system memory. Exemplary contents of an inclusive map cache entry 610 is further depicted in FIG. 6 and includes a LRU field, a WAY field, a PERM field, a PROTECT field, a VALID field, a DIRTY field, and a BAD field. The purpose of the relevant fields in the exemplary map cache entry 610 depicted in FIG. 6 and associated functionality has been mentioned above and additional aspects may be described in further detail below.

In the exemplary configuration depicted in FIG. 6, an addressing schema that consists of a 15-bit page index and an 12-bit page offset is utilized. The memory space visible to the operating system (e.g. 8 Gigabytes) is divided by the size of the first level of memory (e.g. 1 Gigabyte) which determines the number of ways maintained by the inclusive map cache 604. Also, a mapping scheme is established where the DRAM row and column addresses are the same size as the cache page and byte index into a given page. Among other things, this configuration allows a map cache 604 lookup to be executed in parallel with a first level data read. As a result, if a memory address is resident in the first level of memory 602, the requested data may be made available at the same time as the map cache hit/miss information. While the example in FIG. 6 utilizes an addressing schema that consists of an 15-bit page index and an 12-bit page offset, one skilled in the art will recognize that this is merely exemplary and will typically change depending on the exact size and configuration of memory device.

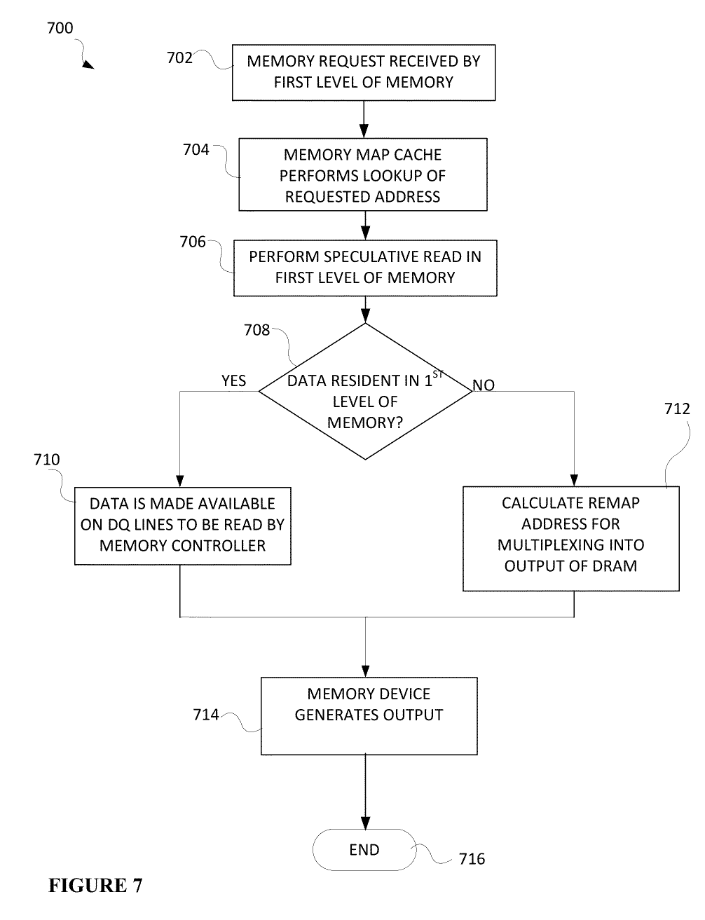

With reference now to FIG. 7, an exemplary method 700 that illustrates the use of an inclusive map cache 602 in accordance with the present disclosure will be described. In this regard, a method 700 will be described with reference to FIG. 7 which illustrates both the logic as well as the interactions between memory components involved in implementing the method 700.

As illustrated in FIG. 7, the method 700 begins at block 702 where a memory request to access data at a specified memory address is communicated to the first level of memory. For example, the first level of memory 604 (FIG. 6) may receive a memory request, at block 702, from an internal or external memory controller which identifies a particular memory address being requested. As is known in the art, the memory request will typically include a memory address. The memory subsystem provided by the present disclosure is responsible for identifying the appropriate way where the data is located and for otherwise resolving the received request.

The memory request received at block 602 is routed to the inclusive map cache 602 maintained in the first level of memory 604. At block 704, a lookup is performed in the inclusive map cache 602 for the requested memory address. The lookup performed at block 704 is implemented in the same way as described above with reference to FIG. 5 at block 503. However, in this instance the WAY field 612 (FIG. 6) for the appropriate inclusive map cache entry is used to determine the location of the requested data.

At block 706, a speculative read operation in the data array of the first level of memory 604 is performed. As mentioned previously, aspects of the present disclosure may implement functionality to perform certain actions in parallel. The memory operation received at block 702 may or may not be requesting data that is currently maintained in the first level of memory 604. In accordance with one embodiment, the present disclosure performs a speculative read of the memory address (at block 706) in parallel with performing a lookup in the memory map cache (at block 704). However, in another embodiment, the memory device provided by the present disclosure implements a power savings mode in which a speculative read operation is not performed in order to minimize power consumption. It may be the case that the data being requested is not currently maintained in the first level of memory 604. In this instance, the speculative read operation performed at block 706 may not successfully access the requested data. However, if the data requested at block 702 is resident in the first level of memory 604, than multiple operations do not have to be performed. If the map cache 602 indicates a hit in the first level of memory 604, the requested data is then immediately available to the memory controller.

At decision block 708 of the method 700, a determination is made regarding whether the requested data is resident in the first level of memory 602 that maintains the inclusive map cache 604. Simply stated, if the results of the lookup in the inclusive map cache 604 performed at block 704 indicate that the requested data is not resident in the first level of memory 602, then the method 700 proceeds to block 712, described in further detail below. Conversely, if the requested data is resident in the first level of memory 602, then the method proceeds to block 710.

At block 710 of the method 700, the requested data is made available on the so called DQ lines for the memory controller to read in accordance with existing systems. The exact manner in which data is provided to the memory controller may depend on the specific memory devices utilized. However, it should be well understood that the method 700 described herein is applicable regardless of which specific memory architecture is employed. Moreover, it should be well understood that the requested data may be made available on any one of a number of different interfaces without departing from the scope of the claimed subject matter. Then, the method proceeds to block 714.

At block 712 of the method 700, a re-map address for the data requested at block 702 is calculated by the inclusive map cache 702. If block 712 is reached, than a determination was made at block 708 that the data being requested is not resident in the first level of managed memory 602. When the requested data is outside the first level of memory, a remap address for the requested data is calculated. In this instance, when a ‘miss’ occurs in the first level of memory, the data and hit/miss information could be made available simultaneously to a memory controller.

As further illustrated in FIG. 7, at block 714, data that is responsive to the memory request received at block 702 is output by the first level of memory 702 provided by the present disclosure. This aspect of the present disclosure was described above with reference to FIG. 1-2. Then, the method 700 proceeds to block 716, where it terminates.

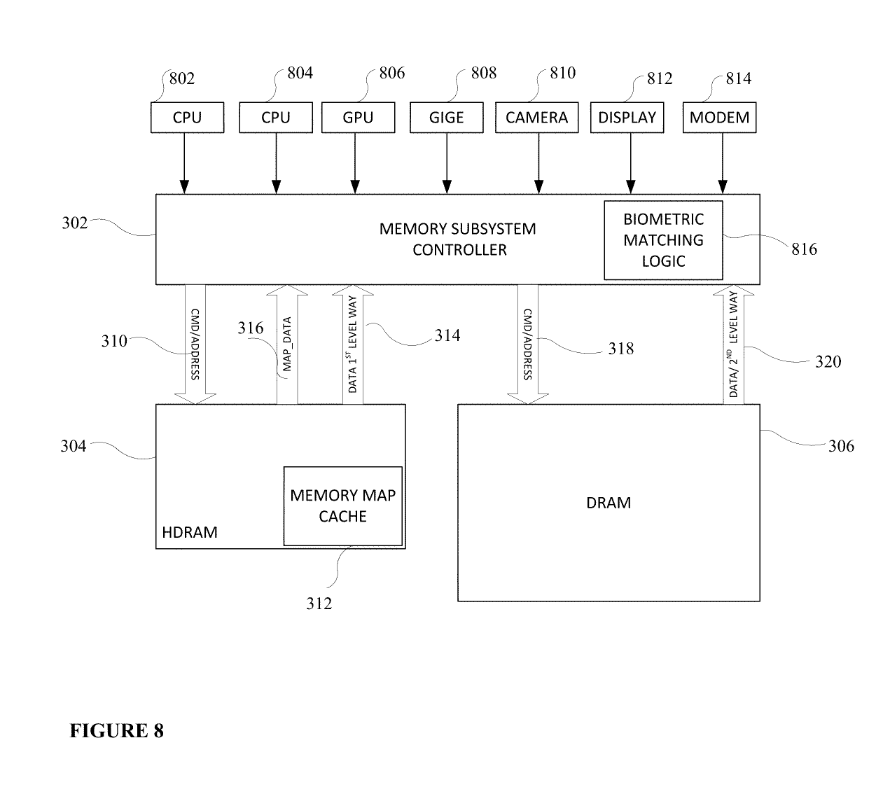

Now with reference to FIG. 8, certain enhanced security features in accordance with the present disclosure will be described. In this regard, FIG. 8 depicts the MSS Controller 302, HDRAM 304, DRAM memory 306, and memory map cache 312 depicted and described above with reference to FIG. 3. However, the system illustrated in FIG. 8, further includes a plurality of memory requesting devices, namely the CPU 802, CPU 804, GPU 806, Giga Ethernet hardware (Gige 808), camera 810, display 812, and modem 814. In this regard, the MSS Controller 302, may receive memory requests from each of the exemplary memory requesting devices 802-814.

In the embodiment depicted in FIG. 8, the MSS Controller 302 includes the embedded biometric matching logic 816. When the biometric matching logic 816 is integrated into a memory subsystem, such as each of the different memory subsystems illustrated and described herein, functionality is provided that allows developers, administrators, and/or users to create protected memory/storage enclaves. These protected memory/storage enclaves may be configured such that users may not be allocated read, write, and/or execute privileges without being biometrically authenticated. While the description herein is made in the context of biometrics, other types of enhanced authentication may be implemented in a memory subsystem provided by the present disclosure without departing from the scope of the claimed subject matter. By way of example, access to physical memory addresses may be restricted and only allowed once the memory controller 302 has authenticated a user utilizing biometrics either alone or in conjunction with user names and passwords, One time Passwords (“OTP”), Personal Identification Numbers (“PIN”), or any other authentication method.

In the exemplary embodiment illustrated in FIG. 8, a memory request may be generated by any one of the devices 802-814. As one skilled in the art will recognize, certain memory resources such as the HDRAM 304 and DRAM memory 306 may be shared in a unified memory architecture in order to efficiently use resources. Accordingly, the memory request may ultimately be generated by any number of different devices, systems, applications, and the like. The memory request is received by the MSS Controller 302 and scheduled for completion. The memory request may include a memory address that identifies a location in OS visible memory. In accordance with one embodiment, certain data in memory is designated as being protected and may only be accessed once a user is biometrically authenticated.

Upon receiving the memory request, the MSS Controller 302 causes a lookup to be performed in the map cache where a cache entry for the page corresponding to the memory address being requested will indicate the protection level. As described above, aspects of the present disclosure include a protection field within the map cache 312 that indicates whether an enhanced security measures, such as biometric authentication, are being applied to control access to a memory address. Aspects of the present disclosure are configured to physically restrict access to blocks of memory without biometric authentication or other enhanced authentication of a user. In response to the request, the first level of managed memory (i.e. the HDRAM 304) returns the MAP DATA output 316 to the MSS Controller 302. The MAP DATA output 316 includes the value of the protection field associated with the requested memory address. This field indicates what, if any, security the MSS Controller 302 will impose on the requestor. The field can be as little as a single bit or can be multiple bits with subfields for write/readability, encryption key and types of protections being utilized. For example, the HDRAM 304 and MSS Controller 302 may support biometric protection for reading, writing, and/or executing data. In this example, the map cache entry for the protection field could consist of three bits (i.e. 100b). When the MSS Controller 302 executes a read of the page with the protection field set to 100b, the map cache entry in the first level of memory (i.e. the HDRAM 304) may indicate that the requested data cannot be provided unless a user is authenticated through biometrics, password, PIN number, OTP, or other enhanced security method and combinations thereof.

The read of the map cache 312 provides the MSS Controller 302 with the enhanced security information for the appropriate memory location. If the received map cache data indicates that enhanced security measures are not implemented for the requested address, the MSS Controller 302 generates the appropriate physical memory address and issues a request to obtain the requested data from the appropriate memory device. As described above, the MSS Controller 302 may obtain the requested data from the first level of memory (i.e. the HDRAM 304) if there is a first level “hit.” Alternatively, the data may be obtained or otherwise accessed from a lower level of memory (i.e. the DRAM 306) using the data returned to the MSS Controller 302. If the received map cache data indicates that the requested address is protected and the requisite authentication has not been completed, than enhanced security measures are implemented before the requested data is accessible. In this instance and in accordance with one embodiment, the MSS Controller 302 may perform an abort operation by returning a binary value of all is (hexadecimal FFFFFFFF) and signaling a memory protection exception. As a result, the OS is able to identify that an enhanced security measure, such as biometric authentication, needs to be completed before the requested data is accessible. The OS or other software may then obtain the appropriate user credentials by, for example, calling the driver of a biometric capture device such as a fingerprint scanner. In turn, a user's biometric data is provided to the MSS Controller 302 for authentication by the Biometric Matching Logic 816.

In one embodiment, the MSS Controller 302 is configured to securely exchange data with the memory requesting devices 802-814 to insure that a memory request does not originate from a rogue device. In addition, the biometric matching logic implemented within the MSS Controller 302 insures that a user is biometrically authenticated before being provided access to requested data. Once biometrically authenticated, a user is then able to make repeated accesses to data for which the user is authorized. In this regard, the MSS Controller 302 and the memory requesting devices 802-814 may exchange keys in order to insure the secure communication of data. In each memory request, a tag or an encryption key is provided that corresponds with the transaction. This data included with the memory request may be derived from some attribute of the user's biometric data. In this regard, a more detailed explanation of the functionality implemented by the Biometric Matching Logic 816 may be found in the following commonly assigned, co-pending US Patent Applications which are hereby incorporated by reference: (1) Patent Application No. 61/709,267 filed, Oct. 3, 2012 entitled “SYSTEM METHODS AND DEVICES OF LINE DETECTION AND QUANTIZATION”; (2) Patent Application No. 61/709,131, filed Oct. 2, 2012 entitled “DIGITAL SIGNAL PROCESSING FILTER FOR BIOMETRIC DATA; and (3) Patent Application No. 61/709,358, filed Oct. 4, 2012 entitled “COMPRESSION OF FINGERPRINT DATA”. In one embodiment, the Biometric Matching Logic 816 implements functionality to determine whether an incoming fingerprint matches the fingerprint data of a previously enrolled user who maintains sufficient security credentials to access the requested data. In another embodiment, the Biometric Matching Logic 816 implements functionality to determine whether incoming heartbeat waveform data matches the waveform data of a user. In yet another embodiment, the Biometric Matching Logic 816 implements functionality to determine whether both incoming fingerprint and heartbeat waveform data matches this same biometric data of a user.

The description provided with reference to FIG. 8 is made in the context of biometrically authenticating a user in a memory subsystem that includes a first level of memory (i.e. the HDRAM) and a second level of memory (i.e. the DRAM). However, this description should be construed as exemplary as the managed access to data and authentication functionality described herein may be implemented in other contexts. For example, the same functionality described with reference to FIG. 8 may be implemented in the memory subsystems described above with reference with reference to FIGS. 1-7. One skilled in the art will recognize that the authentication and security functionality described herein is applicable regardless of the number of different levels or number of memory devices or memory technologies being utilized. Moreover, the authentication and security functionality described herein is applicable in both inclusive and exclusive caching architectures.

While the preferred embodiment of the present disclosure has been illustrated and described, it will be appreciated that various changes can be made therein without departing from the spirit and scope of the disclosed subject matter.

The embodiments of the disclosure in which an exclusive property or privilege is claimed are defined as follows:

1. A memory device having an integrated map cache for managing a memory space, the memory device, comprising:
a first level memory for storing data in a first level of the memory space; and
a memory map cache maintained in the same memory device as the first level memory, the memory map cache configured to map data in the memory space;
wherein common row and address bits are used in the memory map cache and the first level memory and wherein the memory device is further configured to:
receive a request to access a memory address in the memory space; and
cause the memory map cache to perform a lookup of the memory address concurrently with the first level memory accessing data at the requested memory address.

2. The memory device as recited in claim 1, wherein the memory map cache is further configured to:
determine whether data associated with a memory request is currently in the first level memory; and
if the requested data is not in the first level memory, cause a re-map address to be calculated that identifies a location of the requested data in a level of memory lower than the first level memory.

3. The memory device as recited in claim 2, wherein the re-map address is multiplexed into the data stream that is output by the memory device.

4. The memory device as recited in claim 1, wherein the memory map cache is a fully associative cache integrated into a RAM memory device.

5. The memory device as recited in claim 1, wherein the memory map cache implements hardware logic that is not accessible to a software process to map the OS visible memory space.

6. The memory device as recited in claim 1, wherein data maintained in the memory map cache includes a protection field that indicates whether data at a corresponding memory address is associated with an enhanced security measure and wherein the memory device is further configured to generate output that includes the contents of the protection field.

7. The memory device as recited in claim 1, wherein a memory requesting device is not able to access the data at the requested memory address until a biometric trait of a user is authenticated.

8. The memory device as recited in claim 1, wherein data in the memory space that is associated with an enhanced security measure is exclusively maintained in the first level of memory and cannot be evicted to a lower level of memory.

9. A system for managing a memory address space, comprising:
a memory controller operative to generate and communicate a memory request for data in the memory space to a first memory device;
a first memory device comprised of:
a memory for storing data in a first level of the memory space;
a memory map cache within the first memory device configured to map the location of data in the OS visible memory space, wherein the data may be physically stored on the first or second memory devices; and
a second memory device comprised of memory for storing data in a second level of the memory space.

10. The system as received in claim 9, wherein the map cache is further configured to perform a lookup of a memory address across multiple segments in parallel and identify which of the multiple segments holds the memory address.

11. The system as received in claim 9, wherein the memory map cache is further configured to:
determine whether data associated with the memory request is currently stored on the first memory device; and
if the requested data is not stored on the first memory device, cause a re-map address to be calculated that identifies a location of the requested data on a lower level of memory; and
wherein the memory controller is further operative to generate and communicate a memory request to the second memory device for data at the calculated re-map address.

12. The system as received in claim 9, wherein the memory map cache is further configured to map pages into either the first or second levels of memory in the memory space and the existence of pages in at least one of the first and second levels of memory is guaranteed.

13. The system as received in claim 9, wherein the memory map cache is further configured to map a given page into either the first or second levels of memory and all pages in the memory space will be present in at least the second level of memory.

14. The system as received in claim 9, wherein the first memory device is further configured to either satisfy the memory request or provide a re-map address to the memory controller in a single operation.

15. The system as received in claim 9, wherein the memory controller further includes biometric matching logic integrated in hardware logic of the memory controller operative to determine whether incoming biometric data matches the biometric data of an authorized user.

16. The system as received in claim 9, wherein data in the memory space that is designated as protected is stored exclusively in the first memory device and cannot be evicted to a lower level of memory.

17. A method implemented in a memory device having a map cache configured to manage a memory space, the method comprising:
receiving a memory access request from a memory controller;
attempting to access the requested data from a first level of memory maintained on the memory device that contains the map cache;
performing a lookup in the map cache to determine whether the requested address is resident in the first level of memory;
if the requested data is not resident in the first level of memory, causing a re-map address to be calculated that identifies a location of the requested data in a lower level of memory; and
if the requested data is resident in the first level of memory, providing the memory controller with access to the requested data.

18. The method as recited in claim 17, wherein the page index and offset in the map cache uses the same number of address bits as the column and row address in the first level of memory and wherein the attempting to access the requested data from the first level of memory and the lookup in the map cache are performed in parallel.

19. The method as recited in claim 17, wherein performing a lookup in the memory map cache, includes:
determining whether the requested memory address is at a location in memory that requires biometric authentication;
if biometric authentication is required, obtaining biometric information of a user associated with the memory request; and
determining whether the biometric information obtained from the user associated with the memory request matches corresponding biometric information of an authorized user.

20. The method as recited in claim 17, wherein hardware logic is used by the map cache to map the OS visible memory space and wherein performing a lookup in the map cache to determine whether the requested address is resident in the first level of memory includes performing a simultaneous read for the memory address across multiple ways.
